(19) United States
(12) Patent Application Publication
(10) Pub. No.: US 2012/0168768 A1
(43) Pub. Date: Jul. 5, 2012

(54) SEMICONDUCTOR STRUCTURES AND METHOD FOR FABRICATING THE SAME

(75) Inventors: Kuo-Lung FANG, Hsinchu (TW); Chi-Wen KUO, Tainan City (TW); Cheng-Ta KUO, Hsinchu City (TW)

(73) Assignee: LEXTAR ELECTRONICS CORPORATION, Hsinchu (TW)

(21) Appl. No.: 13/340,294

(22) Filed: Dec. 29, 2011

(30) Foreign Application Priority Data
Dec. 30, 2010 (TW) 099146828

(51) Int. Cl. H01L 33/02

(52) U.S. Cl. 257/76; 438/34; 257/E33.023

(57) ABSTRACT

A semiconductor structure is provided. The semiconductor structure includes: a substrate; one or more semiconductor device layers formed on the substrate; and one or more lattice breaking areas formed on the surface of the substrate between the semiconductor device layers. The invention also provides a method for fabricating a semiconductor structure.

### CROSS REFERENCE TO RELATED APPLICATIONS

This Application claims priority of Taiwan Patent Application No. 99146828, filed on Dec. 30, 2010, the entirety of which is incorporated by reference herein.

### BACKGROUND OF THE INVENTION

1. Field of the Invention

The invention relates to a semiconductor structure, and more particularly to an anti-bowing semiconductor structure and a method for fabricating the same.

2. Description of the Related Art

When a light emitting diode (LED) epitaxy is being grown, for example, an epitaxy is grown on a sapphire wafer to form an LED stack structure thereon, due to coefficient of thermal expansion (CTE) and lattice constant differences therebetween, LED wafer bowing is easily caused. When wafer bowing occurs, there is an inconsistency with device wavelength during the temperature-conversion epitaxial growth, which causes alignment error and yield loss during the chipping process. This worsens, for LEDs grown on a large sized (≧3″) sapphire wafer.

At present, the way to resolve the problem of wafer bowing includes performing an etching or deposition process directly on the surface or the back of the sapphire wafer, before epitaxial growth is performed, to fabricate fillisters or protrusions thereon.

### BRIEF SUMMARY OF THE INVENTION

One embodiment of the invention provides a semiconductor structure, comprising: a substrate; one or more semiconductor device layers formed on the substrate; and one or more lattice breaking areas formed on the surface of the substrate between the semiconductor device layers.

One embodiment of the invention provides a method for fabricating a semiconductor structure, comprising: providing a substrate; forming one or more first masks on the substrate; performing a surface treatment procedure on the substrate to form one or more lattice breaking areas on the surface of the substrate; removing the first masks; and forming one or more semiconductor device layers on the substrate between the lattice breaking areas.

The invention uses ion implantation or thermal diffusion etc. combined with patterned masks to perform a surface treatment on, for instance, a sapphire (Al₂O₃) substrate to destroy the lattice bonding thereof. After the surface lattice bonding of the substrate is destroyed, an epitaxial growth process is performed. It is noteworthy that the epitaxial growth cannot be performed on bond breaking areas. However, the epitaxial growth can be performed on raw surface areas. Therefore, the wafer can efficiently reduce the stress caused by the epitaxial growth of a semiconductor device layer on a wafer. Also, the semiconductor device layer may be formed with different shapes by using the surface treatment method.

When the invention is applied to epitaxial growth on a large sized (≧3″) wafer, stress deformation can be reduced resulting in an increase in the consistency of the wavelength of semiconductor devices, for example, an LED, to achieve the purpose of increasing yield.

A detailed description is given in the following embodiments with reference to the accompanying drawings.

### BRIEF DESCRIPTION OF THE DRAWINGS

The present invention can be more fully understood by reading the subsequent detailed description and examples with references made to the accompanying drawings, wherein:

FIG. 1 shows a semiconductor structure according to one embodiment of the invention;

FIGS. 2A-2B show a method for fabricating a semiconductor structure according to one embodiment of the invention;

FIGS. 3A-3B show a method for fabricating a semiconductor structure according to one embodiment of the invention;

FIGS. 4A-4B show a method for fabricating a semiconductor structure according to one embodiment of the invention;

FIGS. 5A-5B show a method for fabricating a semiconductor structure according to one embodiment of the invention; and

FIGS. 6A-6B show a method for fabricating a semiconductor structure according to one embodiment of the invention.

### DETAILED DESCRIPTION OF THE INVENTION

The following description is of the best-contemplated mode of carrying out the invention. This description is made for the purpose of illustrating the general principles of the invention and should not be taken in a limiting sense. The scope of the invention is best determined by reference to the appended claims.

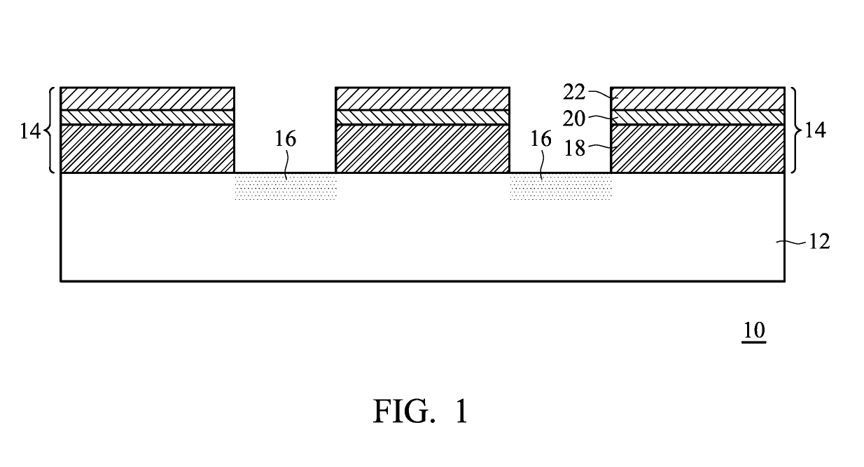

Referring to FIG. 1, in accordance with one embodiment of the invention, a semiconductor structure is provided. A semiconductor structure 10 comprises a substrate 12, one or more semiconductor device layers 14 and one or more lattice breaking areas 16. The semiconductor device layer 14 is formed on the substrate 12. The lattice breaking area 16 is formed on the surface of the substrate 12 between the semiconductor device layers 14.

The substrate 12 may be a sapphire substrate.

The semiconductor device layer 14 may comprise a light emitting diode (LED) or laser diode (LD) structure layer comprising, for example, an N-type semiconductor layer 18, an active layer 20 and a P-type semiconductor layer 22, as shown in FIG. 1. The semiconductor device layer 14 may comprise various shapes such as polygon or hexagon shapes.

The lattice breaking area 16 may be defined as a lattice bond breaking area. In an embodiment, when a sapphire (Al₂O₃) substrate is selected as the substrate 12, after the aluminum-oxygen (Al—O) bond on a partial surface of the substrate is broken through surface treatment, the partial surface is thus formed into the lattice breaking area 16. The lattice breaking area 16 has a width of about 5-40 μm.

The semiconductor structure 10 may further comprise one or more buffer layers (not shown) formed between the semiconductor device layer 14 and the substrate 12. The buffer layer may comprise aluminum nitride (AlN) or aluminum gallium nitride (AlₓGa₁₋ₓN) (0<x<1).

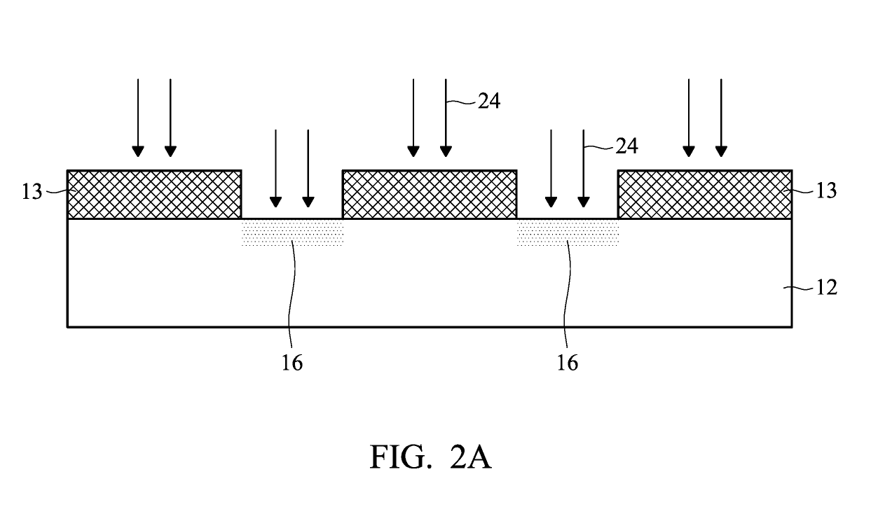

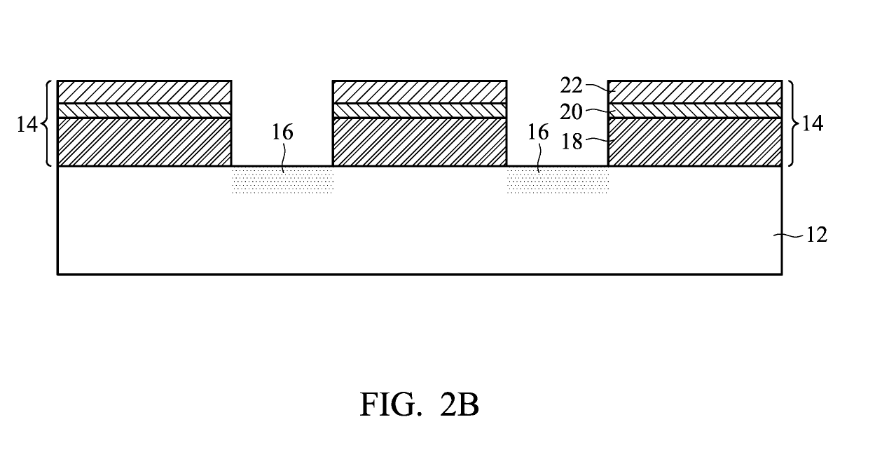

Referring to FIGS. 2A-2B, in accordance with one embodiment of the invention, a method for fabricating a semiconductor structure is provided. First, as shown in FIG. 2A, a substrate 12 is provided. Next, one or more first masks 13 are formed on the substrate 12. A surface treatment procedure 24 is then performed on the substrate 12 to form one or more lattice breaking areas 16 on the surface of the substrate 12. After removal of the first masks 13, one or more semiconductor device layers 14 are formed on the substrate 12 between the lattice breaking areas 16, as shown in FIG. 2B.

The substrate 12 may be a sapphire substrate.

The first mask 13 has a width of about 5-40 μm. The first mask 13 may be a dielectric layer, a metal layer or a photoresist layer.

The surface treatment procedure 24 may comprise an ion implantation process such as a plasma immersion ion implantation process or a thermal diffusion process. In an embodiment, the ion implantation process has an implantation energy less than or equal to 5 kV.

The lattice breaking area 16 may be defined as a lattice bond breaking area. In an embodiment, when a sapphire (Al₂O₃) substrate is selected as the substrate 12, after the aluminum-oxygen (Al—O) bond on a partial surface of the substrate is broken through surface treatment (for example an ion implantation process), the partial surface is thus formed into the lattice breaking area 16. The lattice breaking area 16 has a width of about 5-40 μm. In an embodiment, when the ion implantation process provides a small implantation energy, for example, less than or equal to 5 kV, during the surface treatment procedure 24, the lattice arrangement on the surface of the substrate 12 covered by the first masks 13 is intact due to the first masks 13 having sufficient thicknesses, such that epitaxy formation of the subsequent semiconductor device layers 14 on the substrate 12 is facilitated. However, the lattice arrangement on the surface of the substrate 12 not covered by the first masks 13 is damaged to form the lattice breaking areas 16, as shown in FIG. 2A.

The semiconductor device layer 14 may comprise light emitting diodes (LEDs) or laser diodes (LDs) comprising, for example, an N-type semiconductor layer 18, an active layer 20 and a P-type semiconductor layer 22, as shown in FIG. 2B. The semiconductor device layer 14 may comprise various shapes such as a polygon shape.

The method for fabricating the semiconductor structure further comprises forming one or more buffer layers (not shown) between the semiconductor device layer 14 and the substrate 12 by, for example, an epitaxy method. The buffer layer may comprise aluminum nitride (AlN) or aluminum gallium nitride (AlₓGa₁₋ₓN) (0<x<1).

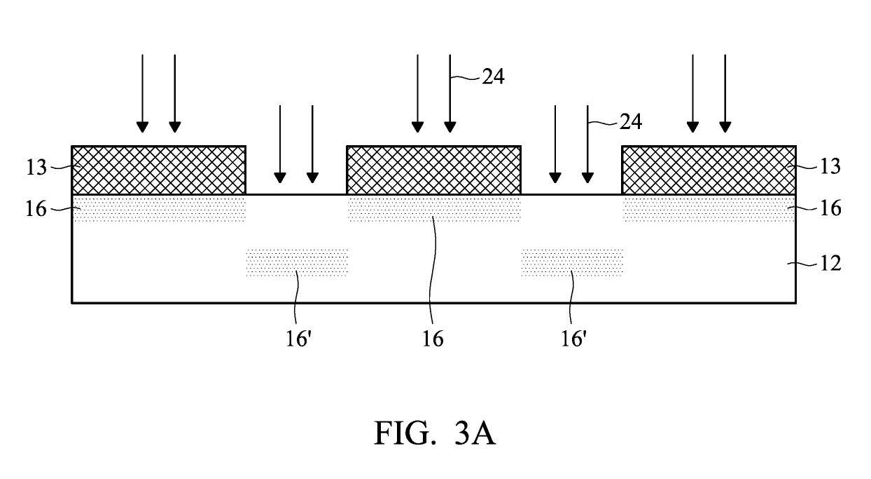

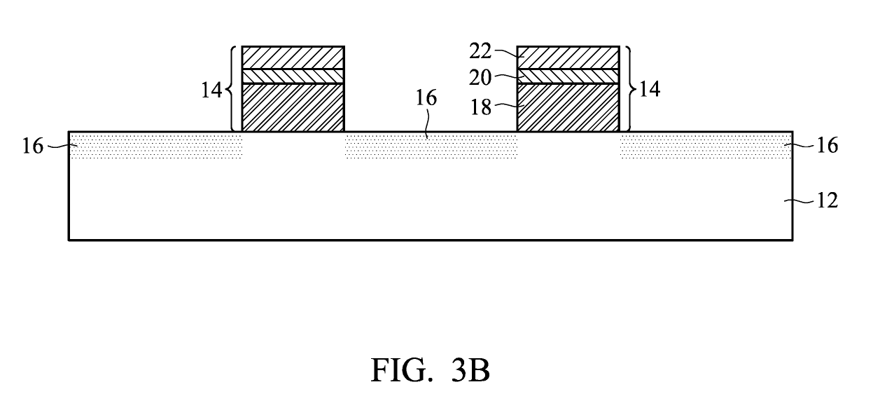

Referring to FIGS. 3A-3B, in accordance with one embodiment of the invention, a method for fabricating a semiconductor structure is provided. First, as shown in FIG. 3A, a substrate 12 is provided. Next, one or more first masks 13 are formed on the substrate 12. A surface treatment procedure 24 is then performed on the substrate 12 to form one or more lattice breaking areas 16 on the surface of the substrate 12. After removal of the first masks 13, one or more semiconductor device layers 14 are formed on the substrate 12 between the lattice breaking areas 16, as shown in FIG. 3B.

The substrate 12 may be a sapphire substrate.

The first mask 13 has a width of about 5-40 μm. The first mask 13 may be a dielectric layer, a metal layer or a photoresist layer.

The surface treatment procedure 24 may comprise an ion implantation process such as a plasma immersion ion implantation process or a thermal diffusion process. In an embodiment, the ion implantation process has an implantation energy greater than or equal to 15 kV.

The lattice breaking area 16 may be defined as a lattice bond breaking area. In an embodiment, when a sapphire (Al₂O₃) substrate is selected as the substrate 12, after the aluminum-oxygen (Al—O) bond on a partial surface of the substrate is broken through surface treatment (for example an ion implantation process), the partial surface is thus formed into the lattice breaking area 16. The lattice breaking area 16 has a width of about 5-40 μm. In an embodiment, when the ion implantation process provides a large implantation energy, for example, greater than or equal to 15 kV, during the surface treatment procedure 24, the lattice arrangement on the surface of the substrate 12 not covered by the first masks 13 is intact due to the large implantation energy passing through the substrate 12 to reach a specific depth thereof to form one or more lattice breaking areas 16′, facilitating epitaxy formation of the subsequent semiconductor device layers 14 on the substrate 12. However, the lattice arrangement on the surface of the substrate 12 covered by the first masks 13 is damaged due to the first masks 13 having a proper thickness to form the lattice breaking areas 16, as shown in FIG. 3A.

The semiconductor device layer 14 may comprise a light emitting diodes (LEDs) or laser diodes (LDs) comprising, for example, an N-type semiconductor layer 18, an active layer 20 and a P-type semiconductor layer 22, as shown in FIG. 3B. The semiconductor device layer 14 may comprise various shapes such as a polygon shape.

The method for fabricating the semiconductor structure further comprises forming one or more buffer layers (not shown) between the semiconductor device layer 14 and the substrate 12 by, for example, an epitaxy method. The buffer layer may comprise aluminum nitride (AlN) or aluminum gallium nitride (AlₓGa₁₋ₓN) (0<x<1).

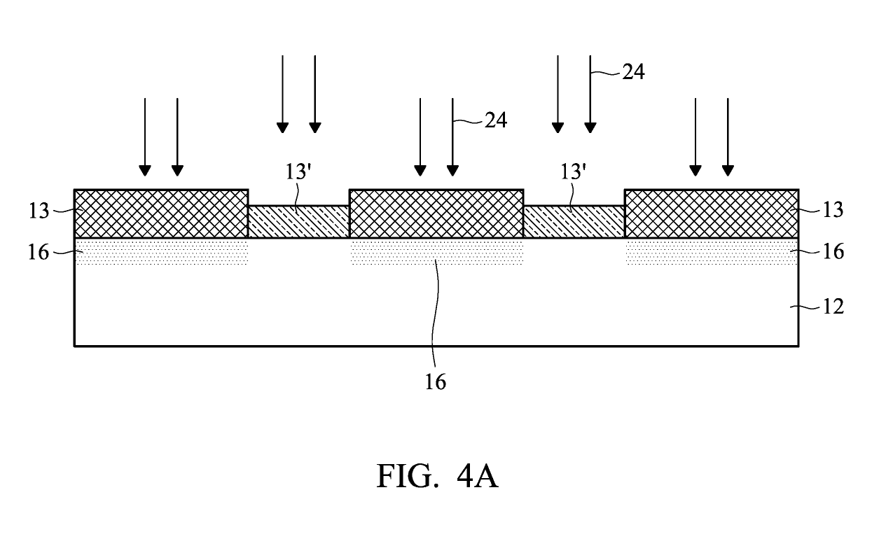

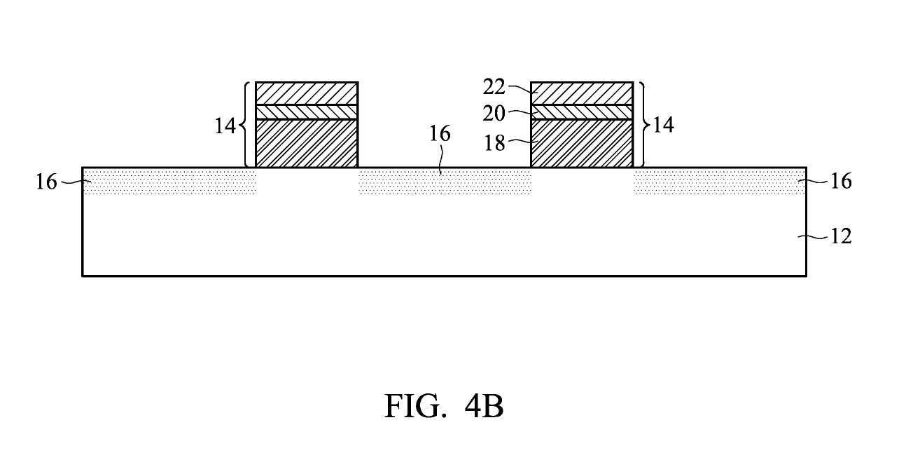

Referring to FIGS. 4A-4B, in accordance with one embodiment of the invention, a method for fabricating a semiconductor structure is provided. First, as shown in FIG. 4A, a substrate 12 is provided. Next, one or more first masks 13 are formed on the substrate 12. A surface treatment procedure 24 is then performed on the substrate 12 to form one or more lattice breaking areas 16 on the surface of the substrate 12. After removal of the first masks 13, one or more semiconductor device layers 14 are formed on the substrate 12 between the lattice breaking areas 16, as shown in FIG. 4B.

The substrate 12 may be a sapphire substrate.

The first mask 13 has a width of about 5-40 μm. The first mask 13 may be a dielectric layer, a metal layer or a photoresist layer.

Still referring to FIG. 4A, in an embodiment, before the surface treatment procedure 24 is performed, the method further comprises forming one or more second masks 13′ on the substrate 12 between the first masks 13. The second mask 13′ and the first mask 13 may have different materials. In an embodiment, when the second mask 13′ and the first mask 13 are different materials, for example, the second mask 13′ is metal (such as nickel, titanium, tungsten, molybdenum or other proper metal materials) and the first mask 13 is silicon oxide or silicon nitride, the second mask 13′ has a thickness less than that of the first mask 13, as shown in FIG. 4A.

The surface treatment procedure 24 may comprise an ion implantation process such as a plasma immersion ion implantation process or a thermal diffusion process. In an embodiment, the ion implantation process has an implantation energy greater than or equal to 15 kV.

The lattice breaking area 16 may be defined as a lattice bond breaking area. In an embodiment, when a sapphire (Al₂O₃) substrate is selected as the substrate 12, after the aluminum-oxygen (Al—O) bond on a partial surface of the substrate is broken through surface treatment (for example an ion implantation process), the partial surface is thus formed into the lattice breaking area 16. The lattice breaking area 16 has a width of about 5-40 μm. In an embodiment, when the ion implantation process provides a large implantation energy, for example, greater than or equal to 15 kV, during the surface treatment procedure 24, the lattice arrangement on the surface of the substrate 12 covered by the second masks 13′ is intact due to the metal second masks 13′ being protected from the implantation energy, facilitating epitaxy formation of the subsequent semiconductor device layers 14 on the substrate 12. However, the lattice arrangement on the surface of the substrate 12 covered by the first masks 13 is damaged due to the first masks 13 having a proper thickness to form the lattice breaking areas 16, as shown in FIG. 4A.

The semiconductor device layer 14 may comprise a light emitting diodes (LEDs) or laser diodes (LDs) comprising, for example, an N-type semiconductor layer 18, an active layer 20 and a P-type semiconductor layer 22, as shown in FIG. 4B. The semiconductor device layer 14 may comprise various shapes such as polygon or hexagon shapes.

The method for fabricating the semiconductor structure further comprises forming one or more buffer layers (not shown) between the semiconductor device layer 14 and the substrate 12 by, for example, an epitaxy method. The buffer layer may comprise aluminum nitride (AlN) or aluminum gallium nitride (AlₓGa₁₋ₓN) (0<x<1).

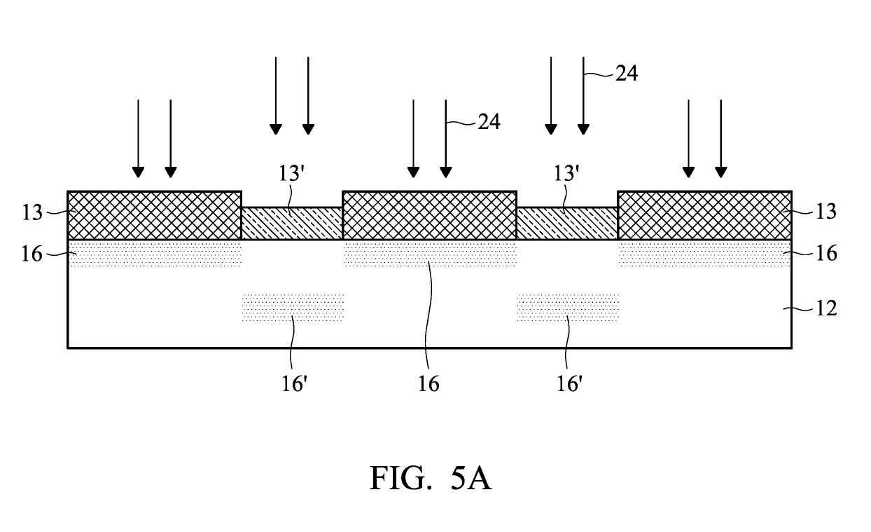

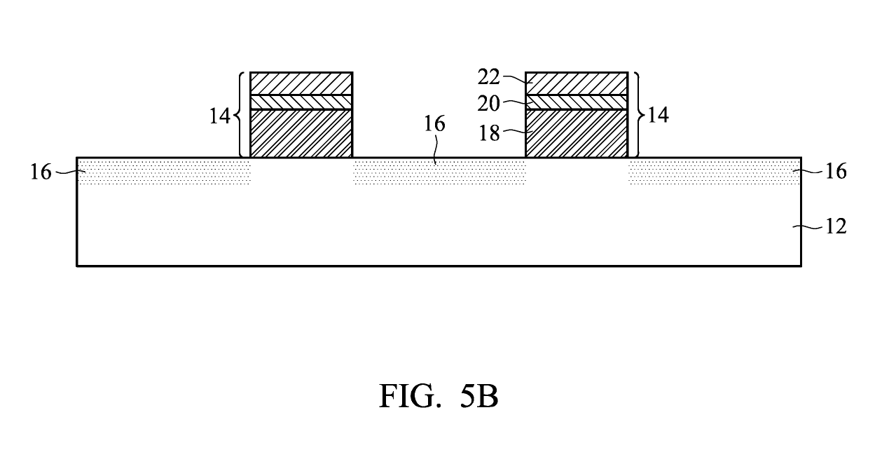

Referring to FIGS. 5A-5B, in accordance with one embodiment of the invention, a method for fabricating a semiconductor structure is provided. First, as shown in FIG. 5A, a substrate 12 is provided. Next, one or more first masks 13 are formed on the substrate 12. A surface treatment procedure 24 is then performed on the substrate 12 to form one or more lattice breaking areas 16 on the surface of the substrate 12. After removal of the first masks 13, one or more semiconductor device layers 14 are formed on the substrate 12 between the lattice breaking areas 16, as shown in FIG. 5B.

The substrate 12 may be a sapphire substrate.

The first mask 13 has a width of about 5-40 μm. The first mask 13 may be a dielectric layer, a metal layer or a photoresist layer.

Still referring to FIG. 5A, in an embodiment, before the surface treatment procedure 24 is performed, the method further comprises forming one or more second masks 13′ on the substrate 12 between the first masks 13. The second mask 13′ and the first mask 13 may have the same material. In an embodiment, when the second mask 13′ and the first mask 13 are the same material, for example, both of the second mask 13′ and the first mask 13 are silicon oxide or silicon nitride, the second mask 13′ has a thickness less than that of the first mask 13, as shown in FIG. 5A.

The surface treatment procedure 24 may comprise an ion implantation process such as a plasma immersion ion implantation process or a thermal diffusion process. In an embodiment, the ion implantation process has an implantation energy greater than or equal to 15 kV.

The lattice breaking area 16 may be defined as a lattice bond breaking area. In an embodiment, when a sapphire (Al₂O₃) substrate is selected as the substrate 12, after the aluminum-oxygen (Al—O) bond on a partial surface of the substrate is broken through surface treatment (for example an ion implantation process), the partial surface is thus formed into the lattice breaking area 16. The lattice breaking area 16 has a width of about 5-40 μm. In an embodiment, when the ion implantation process provides a large implantation energy, for example, greater than or equal to 15 kV, during the surface treatment procedure 24, the lattice arrangement on the surface of the substrate 12 covered by the second masks 13′ is intact due to the thinner second masks 13′ allowing the implantation energy to pass through the substrate 12 to reach a specific depth thereof to form one or more lattice breaking areas 16′, facilitating epitaxy formation of the subsequent semiconductor device layers 14 on the substrate 12. However, the lattice arrangement on the surface of the substrate 12 covered by the first masks 13 is damaged due to the first masks 13 having a proper thickness to form the lattice breaking areas 16, as shown in FIG. 5A.

The semiconductor device layer 14 may comprise a light emitting diodes (LEDs) or laser diodes (LDs) comprising, for example, an N-type semiconductor layer 18, an active layer 20 and a P-type semiconductor layer 22, as shown in FIG. 5B. The semiconductor device layer 14 may comprise various shapes such as polygon or hexagon shapes.

The method for fabricating the semiconductor structure further comprises forming one or more buffer layers (not shown) between the semiconductor device layer 14 and the substrate 12 by, for example, an epitaxy method. The buffer layer may comprise aluminum nitride (AlN) or aluminum gallium nitride (AlₓGa₁₋ₓN) (0<x<1).

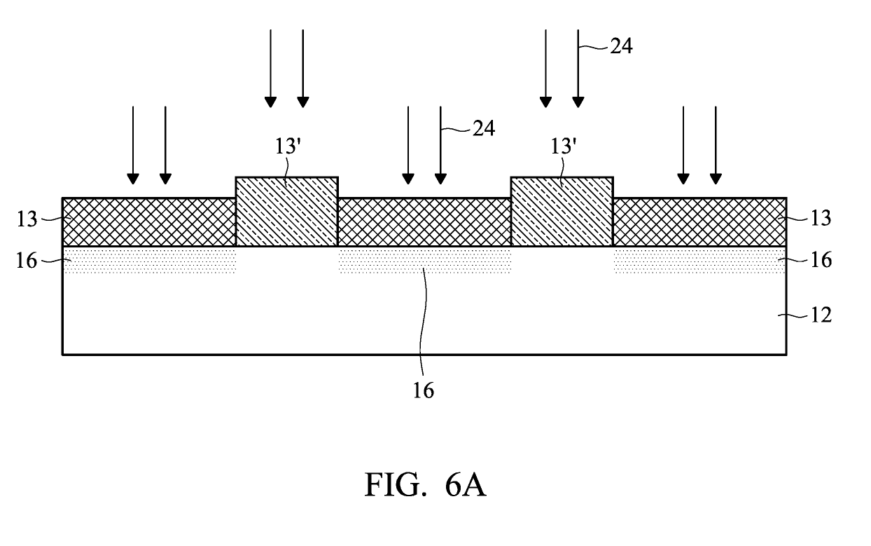

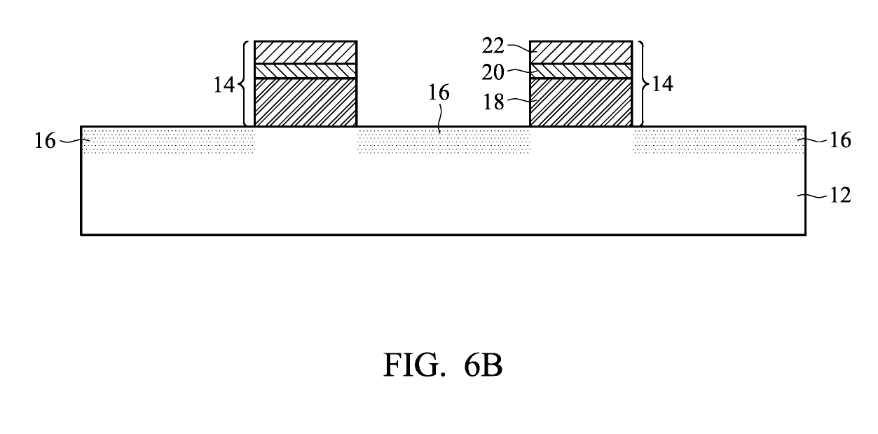

Referring to FIGS. 6A-6B, in accordance with one embodiment of the invention, a method for fabricating a semiconductor structure is provided. First, as shown in FIG. 6A, a substrate 12 is provided. Next, one or more first masks 13 are formed on the substrate 12. A surface treatment procedure 24 is then performed on the substrate 12 to form one or more lattice breaking areas 16 on the surface of the substrate 12. After removal of the first masks 13, one or more semiconductor device layers 14 are formed on the substrate 12 between the lattice breaking areas 16, as shown in FIG. 6B.

The substrate 12 may be a sapphire substrate.

The first mask 13 has a width of about 5-40 μm. The first mask 13 may be a dielectric layer, a metal layer or a photoresist layer.

Still referring to FIG. 6A, in an embodiment, before the surface treatment procedure 24 is performed, the method further comprises forming one or more second masks 13′ on the substrate 12 between the first masks 13. The second mask 13′ and the first mask 13 may have the same material. In an embodiment, when the second mask 13′ and the first mask 13 are the same material, for example, both of the second mask 13′ and the first mask 13 are silicon oxide or silicon nitride, and the second mask 13′ has a thickness greater than that of the first mask 13, as shown in FIG. 6A.

The surface treatment procedure 24 may comprise an ion implantation process such as a plasma immersion ion implantation process or a thermal diffusion process. In an embodiment, the ion implantation process has an implantation energy greater than or equal to 15 kV.

The lattice breaking area 16 may be defined as a lattice bond breaking area. In an embodiment, when a sapphire (Al₂O₃) substrate is selected as the substrate 12, after the aluminum-oxygen (Al—O) bond on a partial surface of the substrate is broken through surface treatment (for example an ion implantation process), the partial surface is thus formed into the lattice breaking area 16. The lattice breaking area 16 has a width of about 5-40 μm. In an embodiment, when the ion implantation process provides a large implantation energy, for example, greater than or equal to 15 kV, during the surface treatment procedure 24, the lattice arrangement on the surface of the substrate 12 covered by the second masks 13′ is intact due to the thicker second masks 13′ being protected from the implantation energy, facilitating epitaxy formation of the subsequent semiconductor device layers 14 on the substrate 12. However, the lattice arrangement on the surface of the substrate 12 covered by the first masks 13 is damaged due to the first masks 13 having a proper thickness to form the lattice breaking areas 16, as shown in FIG. 6A.

The semiconductor device layer 14 may comprise a light emitting diodes (LEDs) or laser diodes (LDs) comprising, for example, an N-type semiconductor layer 18, an active layer 20 and a P-type semiconductor layer 22, as shown in FIG. 6B. The semiconductor device layer 14 may comprise various shapes such as polygon or hexagon shapes.

The method for fabricating the semiconductor structure further comprises forming one or more buffer layers (not shown) between the semiconductor device layer 14 and the substrate 12 by, for example, an epitaxy method. The buffer layer may comprise aluminum nitride (AlN) or aluminum gallium nitride (AlₓGa₁₋ₓN) (0<x<1).

The invention uses ion implantation or thermal diffusion etc. combined with patterned masks to perform a surface treatment on, for instance, a sapphire (Al₂O₃) substrate to destroy the lattice bonding thereof. After the surface lattice bonding of the substrate is destroyed, an epitaxial growth process is performed. It is noteworthy that the epitaxial growth cannot be performed on such bond breaking areas. However, the epitaxial growth can be performed on the raw surface area. Therefore, the wafer can efficiently reduce the stress caused by an epitaxial growth of a semiconductor device layer on a wafer. Also, the semiconductor device layer can be formed with different shapes by using the surface treatment method of the invention.

When the invention is applied to an epitaxial growth process on a large sized (≧3″) wafer, stress deformation can be reduced. Thus, wavelength consistency of semiconductor devices is increased, for example, an LED, to achieve the purpose of increasing yield.

While the invention has been described by way of example and in terms of preferred embodiment, it is to be understood that the invention is not limited thereto. To the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A semiconductor structure, comprising:
a substrate;
one or more semiconductor device layers formed on the substrate; and
one or more lattice breaking areas formed on the surface of the substrate between the semiconductor device layers.

2. The semiconductor structure as claimed in claim 1, wherein the substrate is a sapphire substrate.

3. The semiconductor structure as claimed in claim 1, wherein the semiconductor device layer comprises light emitting diodes or laser diodes.

4. The semiconductor structure as claimed in claim 1, wherein the semiconductor device layer is polygonal.

5. The semiconductor structure as claimed in claim 1, wherein the lattice breaking area is a lattice bond breaking area.

6. The semiconductor structure as claimed in claim 1, wherein the lattice breaking area has a width of 5-40 μm.

7. The semiconductor structure as claimed in claim 1, further comprising one or more buffer layers formed between the semiconductor device layer and the substrate.

8. The semiconductor structure as claimed in claim 7, wherein the buffer layer comprises aluminum nitride (AlN) or aluminum gallium nitride (AlₓGa₁₋ₓN) (0<x<1).

9. A method for fabricating a semiconductor structure, comprising:
providing a substrate;
forming one or more first masks on the substrate;
performing a surface treatment procedure on the substrate to form one or more lattice breaking areas on the surface of the substrate;
removing the first masks; and
forming one or more semiconductor device layers on the substrate between the lattice breaking areas.

10. The method for fabricating a semiconductor structure as claimed in claim 9, wherein the substrate is a sapphire substrate.

11. The method for fabricating a semiconductor structure as claimed in claim 9, wherein the first mask has a width of 5-40 μm.

12. The method for fabricating a semiconductor structure as claimed in claim 9, wherein the surface treatment procedure comprises an ion implantation process or a thermal diffusion process.

13. The method for fabricating a semiconductor structure as claimed in claim 12, wherein the ion implantation process comprises a plasma immersion ion implantation process.

14. The method for fabricating a semiconductor structure as claimed in claim 12, wherein the ion implantation process has an implantation energy less than or equal to 5 kV.

15. The method for fabricating a semiconductor structure as claimed in claim 12, wherein the ion implantation process has an implantation energy greater than or equal to 15 kV.

16. The method for fabricating a semiconductor structure as claimed in claim 9, wherein the lattice breaking area is a lattice bond breaking area.

17. The method for fabricating a semiconductor structure as claimed in claim 9, wherein the lattice breaking area has a width of 5-40 μm.

18. The method for fabricating a semiconductor structure as claimed in claim 9, wherein the semiconductor device layer comprises light emitting diodes or laser diodes.

19. The method for fabricating a semiconductor structure as claimed in claim 9, wherein the semiconductor device layer is polygonal.

20. The method for fabricating a semiconductor structure as claimed in claim 9, further comprising forming one or more buffer layers between the semiconductor device layer and the substrate.

21. The method for fabricating a semiconductor structure as claimed in claim 20, wherein the buffer layer comprises aluminum nitride (AlN) or aluminum gallium nitride (AlₓGa₁₋ₓN) (0<x<1).

22. The method for fabricating a semiconductor structure as claimed in claim 15, further comprising forming one or more second masks on the substrate between the first masks before the surface treatment procedure is performed.

23. The method for fabricating a semiconductor structure as claimed in claim 22, wherein the second mask comprises metal.

24. The method for fabricating a semiconductor structure as claimed in claim 22, wherein the second mask and the first mask have the same material.

25. The method for fabricating a semiconductor structure as claimed in claim 24, wherein the second mask has a thickness greater than that of the first mask.

26. The method for fabricating a semiconductor structure as claimed in claim 24, wherein the second mask has a thickness less than that of the first mask.
